(19) United States
(12) Patent Application Publication
(10) Pub. No.: US 2025/0015018 A1
(43) Pub. Date: Jan. 9, 2025

(54) SEMICONDUCTOR DEVICE INCLUDING SEMICONDUCTOR PACKAGE WITH CAPACITOR EMBEDDED IN DIELECTRIC LAYER

(71) Applicant: SAMSUNG ELECTRONICS CO., LTD., Suwon-si (KR)

(72) Inventor: Jin YANG, San Jose, CA (US)

(73) Assignee: SAMSUNG ELECTRONICS CO., LTD., Suwon-si (KR)

(21) Appl. No.: 18/626,727

(22) Filed: Apr. 4, 2024

Related U.S. Application Data
(60) Provisional application No. 63/524,746, filed on Jul. 3, 2023.

(51) Int. Cl. H01L 23/64; H01L 23/00; H01L 23/538; H01L 25/065

(52) U.S. Cl. CPC H01L 23/642; H01L 23/5383; H01L 24/16; H01L 25/0655; H01L 2224/16227

(57) ABSTRACT

Provided is a semiconductor package which includes: a redistribution layer including at least one insulation layer in which a plurality of wiring patterns are formed; a semiconductor chip, on the redistribution layer, connected to at least one of the plurality of wiring patterns; and a capacitor disposed in the redistribution layer.

### CROSS-REFERENCE TO THE RELATED APPLICATION

This application is based on and claims priority from U.S. Provisional Application No. 63/524,746 filed on Jul. 3 2023 in the U.S. Patent and Trademark Office, the disclosure of which is incorporated herein in its entirety by reference.

### BACKGROUND

### 1. Field

Apparatuses and methods related to a semiconductor device including a semiconductor package in which a capacitor is embedded in a dielectric layer of a redistribution layer.

### 2. Description of the Related Art

As the demand for a semiconductor device including a high device density and high device performance increases, a semiconductor package including a plurality of semiconductor chips and a connections structure such as a redistribution layer is also required to serve high performance of a semiconductor device including the semiconductor package. However, when a semiconductor package is provided with one or more passive devices such as capacitors and resistors, a semiconductor device including one or more of the semiconductor package may have a correspondingly increased size.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

The disclosure provides a semiconductor package or a semiconductor device including the semiconductor package, wherein the semiconductor package includes a dielectric layer of a redistribution layer and a decoupling capacitor embedded in the dielectric layer while the related art semiconductor package includes the decoupling capacitor outside the redistribution layer, for example, a top surface and a bottom surface thereof. For the decoupling capacitor to be embedded in the dielectric layer, an integrated silicon capacitor (ISC) having a very low profile and a high capacitance density may be used. The semiconductor package may be a fan-out wafer level package (FOWLP), not being limited thereto.

According to one or more embodiments, there is provided a semiconductor device which may include: a redistribution layer including at least one insulation layer in which a plurality of wiring patterns are formed; at least one semiconductor chip disposed above or below the redistribution layer, and connected to at least one of the plurality of wiring patterns; and at least one capacitor disposed in the redistribution layer. Here, the capacitor may be an ISC.

According to one or more embodiments, the capacitor may be disposed in the redistribution layer to be closer to a top surface of the redistribution layer facing the semiconductor chip than a bottom surface of the redistribution layer facing away from the semiconductor chip.

According to embodiments, the capacitor may be disposed in the at least one insulation layer such that one of a top surface and a bottom surface of the first capacitor is within the at least one insulation layer, and the other of the top surface and the bottom surface is within the at least one insulation layer or coplanar with a top surface or a bottom surface of the at least one insulation layer

According to embodiments, there is provided an electronic system which may include a first semiconductor package and a second semiconductor package, wherein each of the first and second semiconductor packages includes a redistribution layer in which a plurality of wiring patterns are formed; a semiconductor chip, above or below the redistribution layer, connected to at least one of the plurality of wiring patterns; and a capacitor disposed in the redistribution layer.

According to embodiments, there is provided a method of manufacturing the semiconductor device. The method may include: forming a redistribution layer including at least one insulation layer on a carrier substrate; forming a plurality of wiring patterns in the at least one insulation layer; connecting a capacitor and a wiring pattern among the plurality of wiring patterns each other in the redistribution layer; disposing a semiconductor chip above or below the redistribution layer and connecting the wiring pattern to the semiconductor chip; and removing the carrier substrate. Here, the capacitor may be an integrated silicon capacitor (ISC).

With the capacitor embedded in the redistribution layer, the semiconductor package may achieve power delivery to the semiconductor chip with low impedance and noise, and a smaller footprint in a semiconductor device including the semiconductor package.

### BRIEF DESCRIPTION OF DRAWINGS

Example embodiments of the inventive concept will be more clearly understood from the following detailed description taken in conjunction with the accompanying drawings in which:

FIG. 1 illustrates a schematic cross-section side view of semiconductor package including a plurality of decoupling capacitors, according to an embodiment;

FIG. 2 illustrates a schematic cross-section side view of semiconductor package including a plurality of decoupling capacitors, according to another embodiment;

FIG. 3 illustrates a schematic cross-section side view of semiconductor package including a plurality of decoupling capacitors, according to still another embodiment;

FIG. 4 illustrates a flowchart for a method of manufacturing a semiconductor package including one or more ISCs, according to embodiments; and

FIGS. 5A-5G illustrate intermediate semiconductor packages after respective steps of manufacturing a semiconductor package including one or more ISCs based on the flowchart of FIG. 4, according to embodiments;

FIG. 5A illustrates an intermediate semiconductor package after step 10 of FIG. 4, according to an embodiment;

FIG. 5B illustrates an intermediate semiconductor package after step 20 of FIG. 4, according to an embodiment;

FIG. 5C illustrates an intermediate semiconductor package after step 30 of FIG. 4, according to an embodiment;

FIG. 5D illustrates an intermediate semiconductor package after step 40 of FIG. 4, according to an embodiment;

FIG. 5E illustrates an intermediate semiconductor package after step 50 of FIG. 4, according to an embodiment;

FIG. 5F illustrates an intermediate semiconductor package after step 60 of FIG. 4, according to an embodiment;

FIG. 5G illustrates an intermediate semiconductor package after step 70 of FIG. 4, according to an embodiment; and

FIG. 6 is a schematic block diagram illustrating an electronic device including at least one of the semiconductor packages shown in FIGS. 2 and/or 3, according to an example embodiment.

### DETAILED DESCRIPTION

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “first” element or a “second” element, respectively, as long as their structural relationship is clearly understood in the context of the descriptions. Similarly, the terms a “lower” element and an “upper” element may be respectively referred to as a “first” element and a “second” element with necessary descriptions to distinguish the two elements.

It will be understood that, although the terms “first,” “second,” “third,” “fourth,” “fifth,” “sixth,” etc. may be used herein to describe various elements, these elements should not be limited by these terms. These terms are only used to distinguish one element from another element. Thus, a first element discussed below could be termed a second element without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” or “equal” is used to compare a dimension of two or more elements, the term may cover a “substantially same” or “substantially equal” dimension.

It will be also understood that, when a method of manufacturing an apparatus or structure is described as including a plurality of steps or operations, a certain step or operation described as being be performed later than another step or operation may be performed prior to or at the same time as the other step or operation unless the other step or operation is described as being performed prior to the step or operation. Further, the method may include additional steps or operations not mentioned in the description.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers included in a semiconductor package including a connection pad, an adhesive layer, an isolation layer, a barrier metal pattern, a seed layer, etc. may or may not be described in detail herein. For example, certain connection pads of a semiconductor chip connected to solder balls or bumps in a semiconductor package may be omitted herein when these structural elements are not related to the novel features of the embodiments. Also, descriptions of materials forming well-known structural elements may be omitted herein when those materials are not relevant to the novel features of the embodiments. Herein, the term “connection” between two structures or elements may refer to electrical connection therebetween. For example, connection between semiconductor chips, semiconductor packages, and/or semiconductor devices may refer to electrical connection of corresponding two or more elements to each other. Further, the term “isolation” between two structures or elements pertains to electrical insulation or separation therebetween. For example, isolation of wiring patterns from each other may mean that the wiring patterns are not electrically connected to each other.

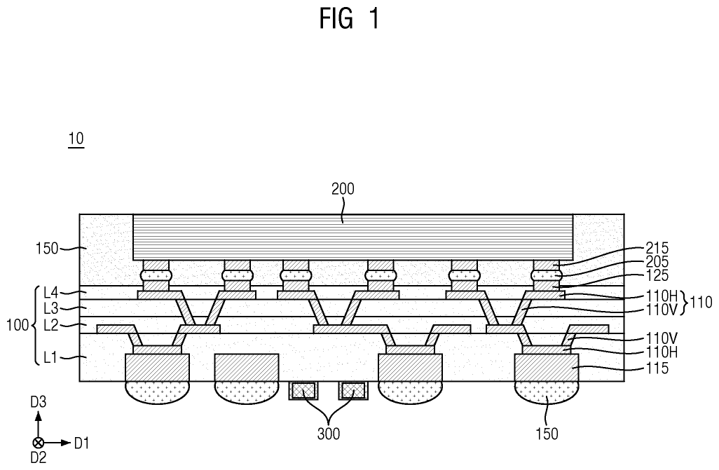

Herebelow, various embodiments of the disclosure are described in reference to FIGS. 1-6.

High-performance semiconductor chips such as a central processing unit (CPU), a graphic processing unit (GPU), an artificial intelligence (AI) chip, etc. consume a greater amount of power compared to other types of semiconductor chip such as a memory chip. For example, power consumption by these high-performance chips may reach a very high level (e.g., around 1000 W) for a thermal design power (TDP). The greater power consumption imposes challenges to designing a power delivery network (PDN) for the high-performance chips, and thus, there is an increased need to design a PDN with a low impedance across multiple frequency ranges when a semiconductor package including the high-performance chips is designed and manufactured.

A semiconductor device may include one or more semiconductor packages each of which includes one or more semiconductor chips. A semiconductor package may include one or more decoupling capacitors to control impedance and remove noise in a power delivery path to one or more semiconductors chip disposed on a redistribution layer in the semiconductor package. As a decoupling capacitor, a semiconductor package of the related art includes one or more capacitors such as a multilayer ceramic capacitor (MLCC), a metal-in-metal (MiM) capacitor, a deep trench capacitor (DTC), etc.

How to configure these decoupling capacitors in a semiconductor package may affect power-delivery performance of a semiconductor device including the semiconductor package in which various high-performance semiconductor chips requiring a greater amount of operation power are included.

FIG. 1 illustrates a schematic cross-section side view of semiconductor package including a plurality of decoupling capacitors, according to an embodiment.

Referring to FIG. 1, a semiconductor package 10 may include a redistribution layer 100, a semiconductor chip 200 disposed vertically above the redistribution layer 100 with a plurality of connection terminals 205 formed between the redistribution layer 100 and the semiconductor chip 200, and a plurality of decoupling capacitors 300 disposed on a bottom surface of the redistribution layer 100.

The semiconductor package 10 may be a fan-out wafer level package (FOWLP) which may be characterized by one or more redistribution layers connecting one or more semiconductor chips or dies to a package substrate. The FOWLP allows for a smaller package size and improved electrical performance compared to other types of semiconductor package such as a fan-in package, a wire-bond package, etc. In the FOWLP, a lateral edge of the package profile may be extended in a D1 direction beyond a lateral edge of a semiconductor chip included therein as shown in FIG. 1. For example, a lateral width of the redistribution layer 100 formed below the semiconductor chip 200 may be greater than that of the semiconductor chip 200. The decoupling capacitors 300 may be provided in the semiconductor package 10 to control impedance and reduce noise applied to the semiconductor chip 200 through the redistribution layer 100.

The semiconductor chip 200 may be one of a system-on-chip (SoC), a microprocessor chip such as a CPU, a GPU, a neural processing unit (NPU), etc., an AI chip, an application-specific integrated circuit (ASIC) chip, an image sensor chip, a power management chip, a memory chip, not being limited thereto. The SoC may include a CPU, a GPU, an NPU or an AI module.

The redistribution layer 100 may include a plurality of wiring patterns 110, lower connection patterns 115 and upper connection patterns 125 connected to each other through the wiring patterns included in a plurality of dielectric layers, for example, first to fourth dielectric layers L1-L4 which are vertically stacked and connected in this order, as shown in FIG. 1.

Each of the wiring patterns 110 included in the dielectric layers L1-L4 may include at least one line part 110H and/or at least one via part 110V connected to each other in a single dielectric layer or across two or more dielectric layers among the dielectric layers L1-L4. For example, a vertical thickness of one line part 110H of the wiring pattern 110 may range 2 to 8 micrometers (μm), and a vertical thickness of each of the dielectric layers L1-L4 may range 3 to 10 micrometers, not being limited thereto. Here, the vertical thickness refers to a thickness measured in a D3 direction that intersects the D1 direction and a D2 direction shown in FIG. 1. Thus, in the dielectric layers L1-L4, one of a top surface and a bottom surface of a line part 110H of the wiring pattern 110 may be disposed within a single dielectric layer, and the other of the top surface and the bottom surface of the line part 110H may be disposed within the single dielectric layer or coplanar with a top surface or a bottom surface of the single dielectric layer. The wiring patterns 110 may also be referred to as wiring traces.

The number of the dielectric layers forming the redistribution layer 100 is four (4) in the present embodiment. However, the disclosure is not limited thereto, and more or less than four (4) dielectric layers may form the redistribution layer 100, according to other embodiments.

A molding layer 150 may be formed to surround the semiconductor chip 200 and fill an underlying gap between the semiconductor chip 200 and the underlying redistribution layer 100.

The redistribution layer 100 may connect a plurality of chip connection pads 215 formed on a bottom surface of the semiconductor chip 200 to a plurality of external terminals 105 on a bottom surface of the redistribution layer 100 so that the semiconductor chip 200 may be connected to one or more external devices or other semiconductor packages. For example, each of the lower connection patterns 115 of the redistribution layer 100 may have at least a portion which is exposed through the bottom surface of the redistribution layer 100 and connected to one of the external terminals 105. Further, each of the upper connection patterns 125 may have at least a portion which is exposed through a top surface of the redistribution layer 100 and connected to one of the chip connection pads 215 through one of the connection terminals 205. The connection terminal 205 and the external terminal 105 may be a solder ball or bump, not being limited thereto.

The wiring patterns 110 may be formed of a metallic material such as copper (Cu), not being limited thereto. The lower connection patterns 115 and the upper connection patterns 125 may be formed of a metallic material such as copper (Cu), aluminum (Al), tungsten, (W), cobalt (Co), ruthenium (Ru), molybdenum (Mo), titanium (Ti), tantalum (Ta), or their compound, not being limited thereto. The connection terminals 205, the bonding pads 215 and the external terminals 105 may be formed of a metallic material such as copper (Cu), tin (Sb), lead (Pb), silver (Ag), or their compound, not being limited thereto. The wiring patterns 110, the lower connection patterns 115, the upper connection patterns 125, the connection terminals 205, the bonding pads 215, and the external terminals 105 may be formed of the same or different metallic materials.

Each of the dielectric layers L1-L4 may be formed of an organic material such as a photosensitive polymer, for example, photosensitive polyimide, not being limited thereto, having insulation properties so that a wiring pattern may be electrically isolated from another wiring pattern in the redistribution layer 100.

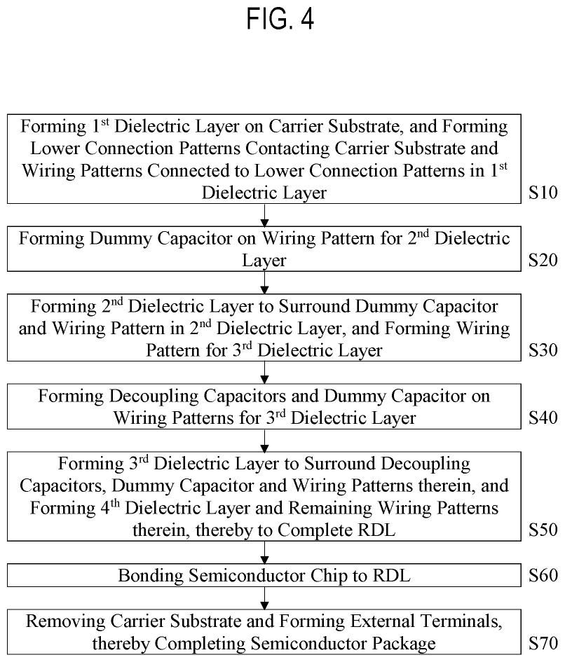

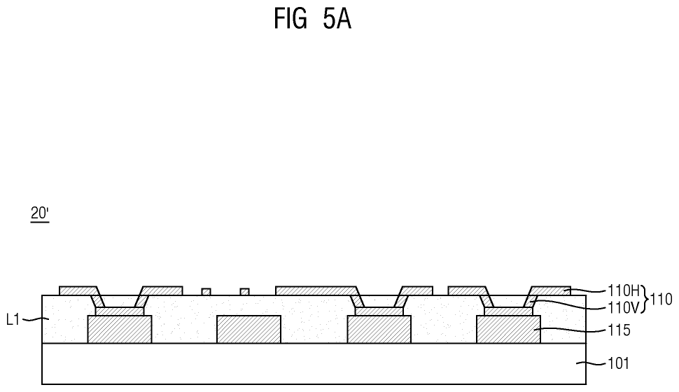

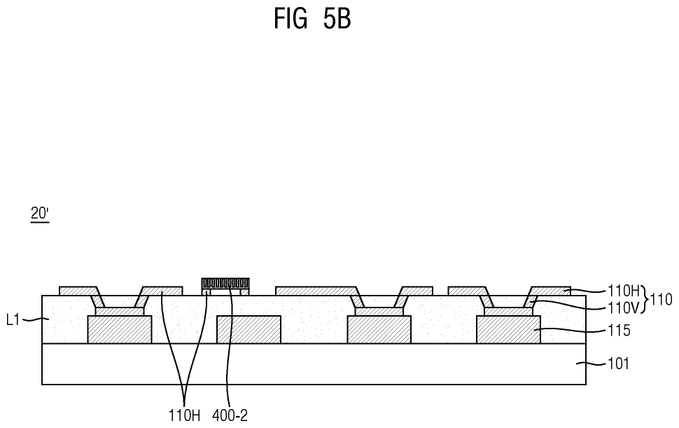

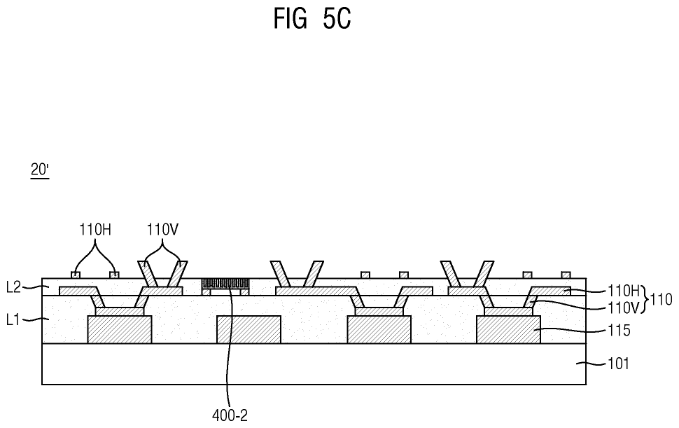

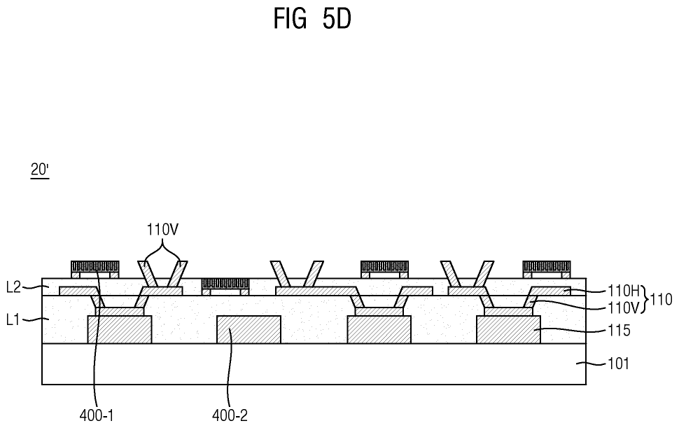

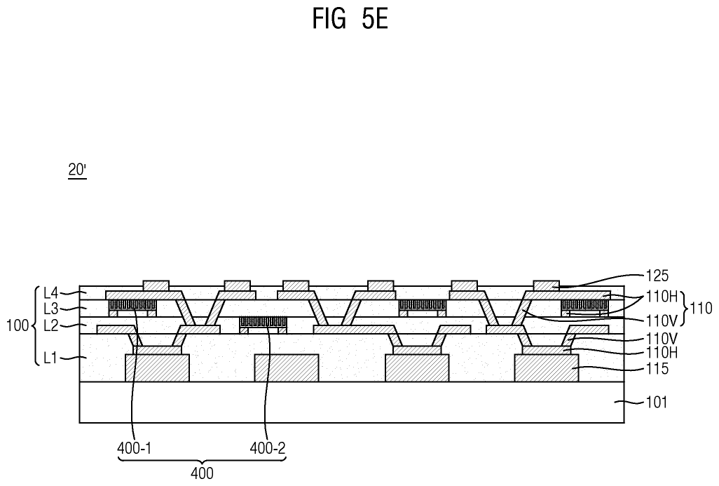

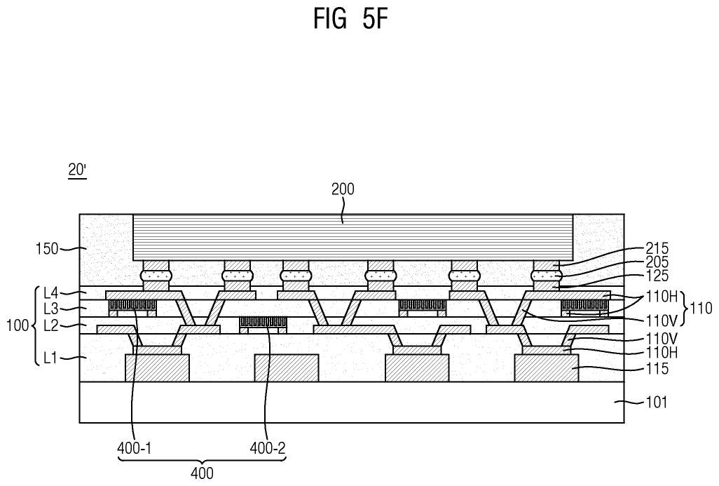

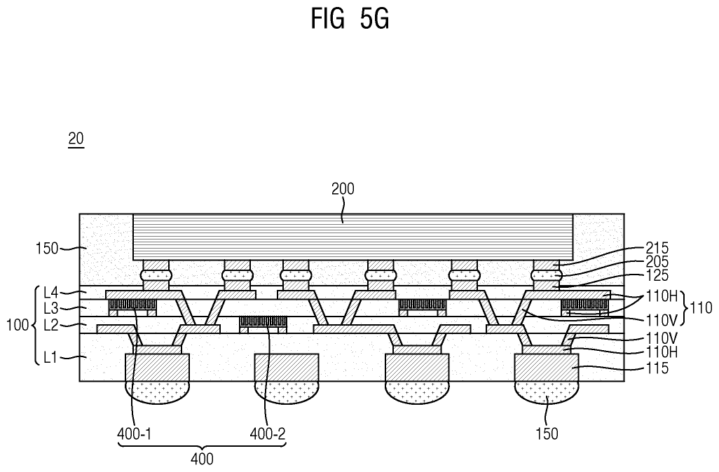

As will be described later in reference to FIGS. 4 to 5A-5G, the dielectric layers L1-L4 may be formed at temporally different steps, and thus, there may exist a boundary, a connection surface or an interface between two adjacent dielectric layers even if they may be formed of the same material. However, there may not exist such boundary, connection surface or interface between the two adjacent dielectric layers even if they may be formed at temporally different steps at least because they may be formed of the same material and through the same process.

As each of the decoupling capacitors 300 is disposed on the bottom surface of the redistribution layer 100, it may be referred to as a land side capacitor (LSC). The decoupling capacitors 300 may be connected or not connected to the wiring patterns 110 in the redistribution layer 100. When the decoupling capacitor 300 is connected to the wiring patterns 110, it may be connected such that at least two terminals thereof are connected to the semiconductor chip 200 in parallel. Each of the decoupling capacitors 300 may have a size of hundreds of micrometers (μm), for example, about 1.0×0.5×0.35 mm for the 0402 MLCC, while each of the dielectric layers L1-L4 may have a much thinner vertical thickness ranging 3 to 10 micrometers. Thus, the semiconductor package 10 may be configured such that the decoupling capacitors 300 are disposed on the bottom surface of the redistribution layer 100 between the external terminals 105 which may be a solder ball or bump. According to another embodiment, however, the semiconductor package 10 may be configured to have a decoupling capacitor on a top surface thereof, in which case this capacitor may be referred to as a die side capacitors (DSC).

Still, however, the decoupling capacitors may not be limited to the MLCC, the MiM capacitor, or the deep trench capacitor, and may also not be necessarily disposed on the bottom or top surface of the redistribution layer 100, as described below.

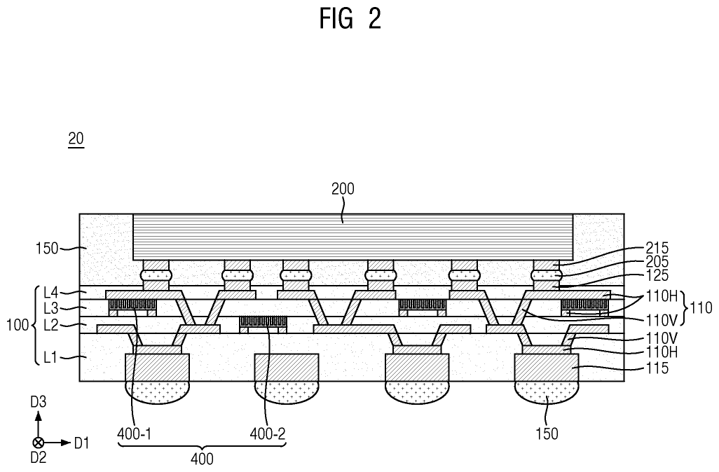

FIG. 2 illustrates a schematic cross-section side view of semiconductor package including a plurality of decoupling capacitors, according to another embodiment.

Referring to FIG. 2, a semiconductor package 20 may include the same or similar structural elements and configuration as that of the semiconductor package 10 shown in FIG. 1 except the decoupling capacitors 300. Thus, duplicate descriptions thereof may be omitted and the same reference numerals referring to those structural elements are used herebelow, while different aspects of the semiconductor package 20 are described herebelow.

The semiconductor package 20 may be characterized by at least a plurality of integrated silicon capacitors (ISCs) 400 that are disposed inside the redistribution layer 100 as decoupling capacitors for the semiconductor package 20, compared to the capacitors 300 disposed on a bottom surface of the redistribution layer 100.

The ISC 400 may take a form of a vertical cylinder array including a plurality of capacitive vias between two or more connection terminals, and may have a very low profile, for example, about 0.5 mm×0.5 mm×2.0 μm. Thus, the vertical thickness of the ISC 400 in the D3 direction may be smaller than that of each of the dielectric layers L1-L4 which may range 3 to 10 micrometers, so that the ISC 400 may be embedded in each of the dielectric layers L1-L4, or across two or more of the dielectric layers L1-L4. Further, the ISC 400 may have a high capacitance density similar to that of the MLCC. For example, the ISC may have hundreds of nF/mm² capacitance values, e.g., 1350 or higher nF/mm².

Due to the above-described low profile and high capacitance density, the ISC 400 may be embedded inside the redistribution layer 100 at a desired location for the same functional purpose of the decoupling capacitors 300 shown in FIG. 1. As the ISC 400 may have a small thickness than each of the dielectric layers L1-L4, the ISC 400 may be included in one of these dielectric layers such that one of a top surface and a bottom surface of the ISC 400 is within the single dielectric layer (e.g., L2 or L3), and the other of the top surface and the bottom surface of the ISC 400 is within the single dielectric layer or coplanar with a top surface or a bottom surface of the single dielectric layer.

The ISC 400 may be either a first ISC 400-1 or a second ISC 400-2. The first ISC 400-1 may be connected to the at least one of the wiring patterns 110. For example, the first ISC 400-1 may be interposed between a line part 110H of a wiring pattern 110 in one dielectric layer (e.g., L3) and a line part 110H of a wiring pattern 110 in an adjacent dielectric layer (e.g., L4). The line part 110H of the wiring pattern 110 in the dielectric layer L3 may be extended in the D2 direction while the line part 110H of the wiring pattern 110 in the dielectric layer L4 may be extended the D1 direction. These two wiring patterns 110 connected to the first ISC 400-1 in two adjacent dielectric layers may be connected to a power delivery path between a voltage source and the semiconductor chip 200. The power delivery path may include the external terminals 105, the lower connection patterns 115, the wiring patterns 110, the upper connection patterns 125, the connection terminals 205, and the chip connection pads 215. As another example, the second ISC 400-2 may be formed on a line part 110H extended in the D2 direction in one dielectric layer (e.g., L2 and L3), but may be not connected to the power delivery path connecting the voltage source to the semiconductor chip 200. Thus, the second ISC 400-2 may function as a dummy capacitor, which may only support the structural configuration of the redistribution layer 100.

The wiring patterns 110 may also connect the semiconductor chip 200 to another semiconductor chip or a circuit element in another semiconductor package or semiconductor device. For example, a signal routing path may be formed through one of the connection pads 215, one of the connection terminals 205, one of the upper connection patterns 125, one or more of the wiring patterns 110 connected to the one of the first ISCs 400-1, one of the lower connection patterns 115, and one of the external terminals 105.

While the thickness of each of the line part 110H of the wiring pattern 100 and the ISC 400 may be smaller than a signal dielectric layer among the dielectric layers L1-L4, the wiring pattern 100 with the ISC 400 thereon may also have a thickness small than or equal to that of the single dielectric layer. For example, while a bottom surface of the line part 110H of the wiring pattern 100 extended in the D2 direction in the third dielectric layer L3 may be coplanar with a boundary between the third dielectric layer L3 and the second dielectric layer L2, a top surface of the ISC 400 formed on this line part 110H of the wiring pattern 100 may be coplanar with a boundary between the third dielectric layer L3 and the fourth dielectric layer L4. Thus, a sum thickness of the line part 110H of the wiring pattern 110 and the IDC 400 in the third dielectric layer L3 may be equal to the thickness of the dielectric layer L3. However, the disclosure is not limited thereto, and the wiring pattern 100 with the ISC 400 thereon may have a thickness greater or smaller than that of a single dielectric layer in the redistribution layer 100 according to embodiments. Still, however, the sum thickness of the line part 110H of the wiring pattern 110 and the IDC 400 may be smaller than a thickness of the redistribution layer 100 according to embodiments, Further, a sum thickness of the wiring pattern 110 including the line part 110H and the via part 110V may be smaller than the thickness of the redistribution layer 100 according to embodiments.

The ISC 400 having a high capacitance density may be disposed in the redistribution layer 100 sufficiently close to the semiconductor chip 200, for example, closer to the top surface than the lower surface of the redistribution layer 100, to better control impedance and noise applied to the semiconductor chip 200, thereby improving power delivery performance.

Further, as the semiconductor package 20 may dispense with DSCs or LSCs like the capacitors 300 in the semiconductor package 10 which are disposed on the top surface or the bottom surface of the redistribution layer 100 as shown in FIG. 1, an overall size of the semiconductor package 20 may be reduced. For example, while the external terminal 105, which may be a solder ball or bump, may form a ball grid array (BGA) of the semiconductor package 10 and 20, removal of the capacitors 300, which are LSCs, formed between the external terminals 105 on the bottom surface of the redistribution layer 100 may reduce constraints on a package design including a ball design for a BGA semiconductor package.

In the semiconductor package 10 shown in FIG. 1, a height in the D3 direction of the external terminal 105 of the semiconductor package 100 may be greater than that of the capacitor 300 formed on the bottom surface of the redistribution layer 100 at a side of the external terminal 105 so that the capacitor 300 may not be physically affected by connection of the semiconductor package 10 with another device or package through the external terminal 1005. However, in the semiconductor package 20 of the present embodiment, the height of the external terminal 105 may not be constrained because there is no such capacitor 300 on the bottom surface of the redistribution layer 100. For example, the external terminals 105 may be formed by smaller-sized solder balls at a smaller pitch and profile, which helps reduce an overall stack-up height of the semiconductor package 20.

The above embodiment of disposing the ISCs 400 inside the redistribution layer 100 may also apply to a land grid array (LGA) semiconductor package, that is, the semiconductor package 20 without the external terminals 105 (solder balls or bumps). In this case, the lower connection patterns 115 may form the LGA, and elimination of the capacitors 300 from the bottom surface of the redistribution layer 100 as an LSC may remove a need of a cavity inside an original equipment manufacturer (OEM) socket to improve a structural integrity with the OEM socket. Thus, manufacturing simplicity and cost reduction may also be achieved.

Moreover, due to the low impedance and the high capacitance density of the ISCs 400 in the semiconductor package 20 having a reduced footprint may better serve implementation of the high performance processors such as CPU, GPU, AI chips, etc. requiring high power consumption in a semiconductor package.

In the above embodiments, one redistribution layer, that is, the redistribution layer 100, is formed in the semiconductor package 20 to connect the semiconductor chip 200 to a voltage source or another semiconductor device or package through the external terminals 105. However, one or more additional redistribution layers may be formed above, below or at a side of the redistribution layer 100 in the semiconductor package 20 to provide at least one additional redistribution path to the semiconductor chip 200, according to embodiments. For example, the semiconductor chip 200 may be connected to another circuit element or semiconductor chip in another semiconductor package or device through the additional redistribution path provided by the additional redistribution layers in the semiconductor package 20. Here, the additional redistribution path may be a power delivery path or a signal routing path from or to the semiconductor package 20.

As one or more additional redistribution layers are connected to the semiconductor chip 200, a length of the power delivery path or the signal routing path may also increase, which may subsequently increase impedance and/or noise in the semiconductor package 20. However, one or more ISCs 400 may also be included in the additional redistribution layers to reduce the impedance and/or noise, and suppress increase of the entire size of the semiconductor package 20, according to embodiments.

In the meantime, the redistribution layer 100 with the ISCs 400 embedded therein may be disposed vertically above the semiconductor package 20 with corresponding connection patterns and terminals therebetween, thereby to form a different semiconductor package, according to another embodiment. In this embodiment, the ISCs 400 may be disposed in the redistribution layer 100 to be closer to a bottom surface of the redistribution layer 100 than a top surface thereof to better control impedance and noise applied to the semiconductor chip 200 disposed vertically below the redistribution layer 100.

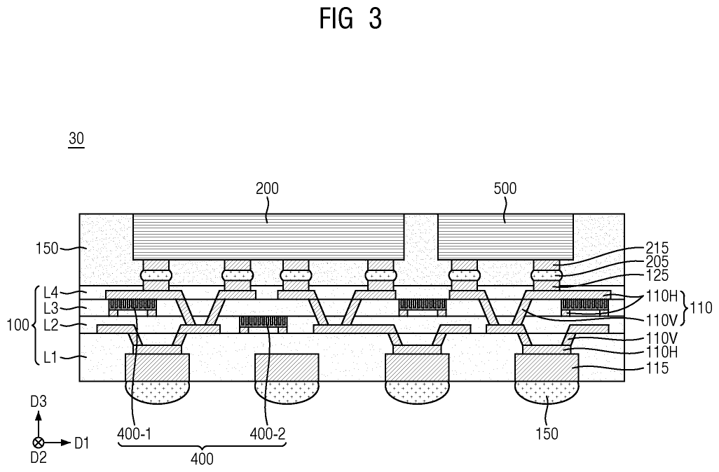

Further, two or more semiconductor chips may be formed vertically above or below a redistribution layer including ISCs with corresponding connection patterns and terminals therebetween. FIG. 3 illustrates a schematic cross-section side view of semiconductor package including a plurality of decoupling capacitors, according to still another embodiment.

Referring to FIG. 3, a semiconductor package 30 may include the same or similar structural elements including the ISCs 400 and configuration as that of the semiconductor package 20. However, the semiconductor package 30 may be characterized in that another semiconductor chip 500 may be disposed vertically above the redistribution layer 100 within the lateral edges of the package profile. Thus, duplicate descriptions thereof may be omitted, and the same reference numerals referring to those structural elements are used herebelow.

Similar to the semiconductor package 20, the semiconductor package 30 may include the ISCs 400 inside the redistribution layer 100, and the ISCs 400 may each be either the ISC 400-1 or the ISC 400-2 as described above in reference to FIG. 2. However, in the semiconductor package the ISCs 400-1 may be connected to the semiconductor chips 200 and 500 to control impedance and noise applied to these two chips, respectively. The semiconductor package 30 may also provide a reduced footprint like the semiconductor package 20 as the LSCs or DSCs may not be included in the semiconductor package 30.

In the semiconductor package 30, the semiconductor chips 200 and 500 may be connected to each other through the wiring patterns 110 in the redistribution layer 100, in which case, the semiconductor chips 200 and 500 may be connected to the same one or more ISCs 400, and these ISCs 400 may be connected to a voltage source to reduce impedance and noise in the power delivery path. Additionally or alternatively, these ISCs 400 may be included in a signal routing path between the two semiconductor chips 200 and 500 to reduce impedance and noise in the signal routing path.

In FIG. 3, the two semiconductor chips 200 and 500 are formed vertically above one redistribution layer, that is, the redistribution layer 100, which includes the ISCs 400 in the semiconductor package 30. However, the disclosure is not limited thereto, and the semiconductor package 30 may be configured such that one or more additional redistribution layers may be formed above, below or at a side of the redistribution layer 100 in the semiconductor package 30 to provide at least one additional redistribution path to at least one of the semiconductor chips 200 and 500, according to embodiments. For example, at least one of the semiconductor chips 200 and 500 may be connected to another circuit element or semiconductor chip in another semiconductor package or device through the additional redistribution path provided by the additional redistribution layers in the semiconductor package 30.

As one or more additional redistribution layers are connected to at least one of the semiconductor chips 200 and 500, a length of the power delivery path or the signal routing path may also increase, which may subsequently increase impedance and/or noise in the semiconductor package 30. However, one or more ISCs 400 may also be included in the additional redistribution layers to reduce the impedance and/or noise and suppress increase of the entire size of the semiconductor package 30, according to embodiments.

Further, FIG. 3 shows that the semiconductor chips 200 and 500 are disposed side by side at a same level above the redistribution layer 100 in the semiconductor package 30. However, the disclosure is not limited thereto, and the semiconductor chips 200 and 500 may be formed at different levels above the redistribution layer 100, according to embodiments. For example, one or more additional redistribution layers may be formed below a higher-level semiconductor chip among the two semiconductor chips 200 and 500, and the additional redistribution layers may provide at least one additional redistribution path to the semiconductor package 30. Similar to the above embodiment, one or more ISCs 400 may be included in the additional redistribution layers to reduce the impedance and/or noise, and suppress increase of the entire size of the semiconductor package 30.

Herebelow, a method of manufacturing a semiconductor package including one or more ISCs is provided in reference to FIG. 4 and FIGS. 5A-5G.

FIG. 4 illustrates a flowchart for a method of manufacturing a semiconductor package including one or more ISCs, according to embodiments, and FIGS. 5A-5G illustrate intermediate semiconductor packages after respective steps of manufacturing a semiconductor package including one or more ISCs based on the flowchart of FIG. 4, according to embodiments.

The semiconductor package manufactured through the method described herebelow may be the same as or correspond to the semiconductor package 20 shown in FIG. 2, and thus, duplicate descriptions may be omitted and the same reference numerals referring to the structural elements of the semiconductor package 20 are used herebelow.

In step S10, the first dielectric layer L1 may be formed on a carrier substrate 101 through a coating or deposition process, as shown in FIG. 5A. Further, a first photolithography/masking/etching/deposition operation may be performed on the first dielectric layer L1 to form the lower connection patterns 115, the line part 110H and the via part 110V of each the wiring patterns 110 connected to the lower connection pattern 115 in the first dielectric layer L1. In addition, the line parts 110H of the wiring patterns 110 for the second dielectric layer L2 to be formed in a later step above the dielectric layer L1 may also be formed by the first photolithography/masking/etching/deposition operation in this step. Some of these line parts 110H for the second dielectric layer L2 may be formed to be extended in the D1 direction and connected to the lower connection patterns 115 through the wiring patterns 110 in the first dielectric layer L1, and some of these line parts 110H may be formed to be extended in the D2 direction and connected to the ISC 400 in a later step.

The first dielectric layer L1 may be patterned through, for example, lithography, laser drilling, reactive ion etching (RIE), etc., to form via openings which are subsequently filled in by depositing one or more metallic materials through, for example, electroplating, atomic layer deposition (ALD), physical vapor deposition (PVD), chemical vapor deposition (CVD), plasma enhanced CVD (PECVD), a combination thereof, etc., not being limited thereto, to form the lower connection patterns 115 and the wiring patterns 110. The lower connection patterns 115 may be formed such that bottom surfaces thereof contact the carrier substrate 101.

The metallic materials forming the lower connection patterns 115 and the wiring patterns 110 may be selected from among copper (Cu), aluminum (Al), tungsten, (W), cobalt (Co), ruthenium (Ru), molybdenum (Mo), titanium (Ti), tantalum (Ta), or their compound, not being limited thereto. The lower connection patterns 115 and the wiring patterns 110 may be formed of the same or different materials.

The carrier substrate 101 on which the first dielectric layer L1 is formed may be, for example, a glass, silicon or ceramic substrate, not being limited thereto. The coating or deposition process to form the dielectric layer L1 may use spin coating, slit coating, CVD, etc. of the organic material such as a photosensitive polymer, for example, photosensitive polyimide, not being limited thereto.

In step S20, the second ISC 400-2 may be formed on at least one line part 110H of at least one selected wiring pattern 110 for the dielectric layer L2, as shown in FIG. 5B. The second ISC 400-2 may be formed on the wiring pattern 110 extended in the D2 direction through, for example, soldering, not being limited thereto.

The second ISC 400-2 formed in this step may be a dummy capacitor which is not connected to the power delivery path in the semiconductor package 20 to be completed in a later step based on an intermediate semiconductor package obtained in this step.

In step S30, the second dielectric layer L2 may be formed on the first dielectric L1 by the same or similar coating or deposition process performed in step S10 to surround the wiring patterns 110 in the second dielectric layer L2, as shown in FIG. 5C. Further, a second photolithography/masking/etching/deposition operation may be performed to form the line parts 110H of the wiring patterns 110 for the third dielectric layer L3 and the via parts 110V of the wiring patterns 110 connected to the line part 110H thereof in the second dielectric layer L2. These line parts 110h may be formed to be extended in the D2 direction and connected to the ISCs 400 in a later step.

In step S40, the ISCs 400-1 and another ISC 400-2 may be formed on the respective line parts 110H of selected wiring patterns 110 for the third dielectric layer L3 through soldering as in step S20, not being limited thereto, as shown in FIG. 5D

Like the ISC 400-2 formed in the second dielectric layer L2 in step S20, the ISC 400-2 formed in this step may not be connected to the power delivery path in the semiconductor package 20 to be completed in a later step. However, the ISCs 400-1 formed in this step may be connected to the power delivery path in the semiconductor package 20.

In step S50, the third dielectric layer L3 may be formed on the second dielectric layer to surround the wiring patterns 110 formed in step S40 and the ISCs 400-1 and 400-2 thereon, as shown in FIG. 5E.

Further, the fourth dielectric layer L4 may be formed on the third dielectric layer L3 by the same or similar coating or deposition process performed in steps S10 and S30, thereby completing the redistribution layer 100. In addition, a third photolithography/masking/etching/deposition operation may be performed on the fourth dielectric layer L4 to form the remaining line parts 110H of the wiring patterns 110 on the respective via parts 110V of the wiring patterns 110 in the third dielectric layer L3, and form the upper connection patterns 125 on these line parts 110H of the wiring patterns 110.

In step S60, the connection terminals 205 may be formed on the upper connection patterns 125 respectively, and the semiconductor chip 200 may be seated on the redistribution layer 100 by bonding the chip connection pads 215 thereof to the connection terminals 205, respectively, as shown in FIG. 5F. Further, the molding layer 150 may be formed to surround the semiconductor chip 200 and fill an underlying gap between the semiconductor chip 200 and the underlying redistribution layer 100.

When the connection terminals 205 are solder balls or bumps, solder transfer, ball placement, electroplating, printing, or the like may be used to form the connection terminals 205 on the upper connection patterns 125. Bonding the semiconductor chip 200 to the connection terminals 205 may be performed through, for example, soldering. The connection terminals 205 and the bonding pads 215 may be formed of the same or different metallic materials selected from among copper (Cu), tin (Sb), lead (Pb), silver (Ag), or their compound, not being limited thereto.

In step S70, as shown in FIG. 5G, the carrier substrate 101 may be removed from the intermediate semiconductor package obtained in the previous step, and the external terminals 105 may be formed on the bottom surface of the redistribution layer 100 to be connected to the lower connection patterns 115, respectively, thereby forming the semiconductor package 20 shown in FIG. 2.

The external terminals 105 may be formed of a metallic material such as copper (Cu), tin (Sb), lead (Pb), silver (Ag), or their compound, not being limited thereto. The external terminals may be formed of the same or different materials from the connection terminals 205.

The removal of the carrier substrate 101 may be performed through, for example, mechanical grinding, etc., and the connection of the external terminals 105 to the lower connection patterns 115 may be performed through, for example, soldering, etc.

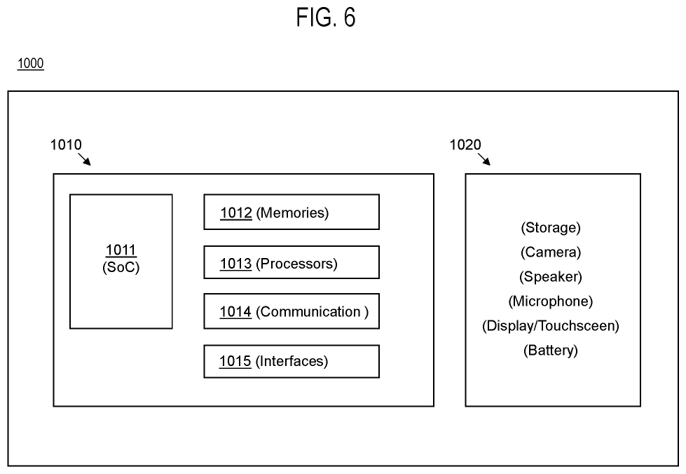

FIG. 6 is a schematic block diagram illustrating an electronic system including a plurality of semiconductor packages shown in FIGS. 2 and/or 3, according to an example embodiment.

Referring to FIG. 6, an electronic device 1000 may include a printed circuit board (PCB) 1010, which may be a motherboard, on which a plurality of semiconductor packages 1011-1015 are mounted. The electronic device 1000 may also include a plurality of other components 1020. The PCB 1010 may be a package substrate which includes a substrate core formed of an epoxy resin and a plurality of through vias penetrating the substrate core. The package substrate may also include a plurality of connection terminals formed on a front side surface and/or a backside surface, and connected to the through vias. The package substrate may be connected to a redistribution layer such as the redistribution layer 100 of FIG. 2 or 3.

The semiconductor package 1011 may include a SoC which may include at least one of a CPU, a GPU, an AI module, a modem, one or more memory units, a power management unit, etc. to control overall operations of the electronic device 1000. The other semiconductor packages 1012-1015 may include memory chips, various other processor chips, communication chips and interface chips, respectively. The communication chips included in the semiconductor package 1014 may be configured to also perform wireless or wire communication functions in association with the SoC. At least one of the semiconductor packages 1011-1015 may be implemented by the semiconductor package 20 or 30 shown in FIGS. 2A and 3A.

The other components 1020 included in the electronic device 100 may include a storage, a camera module, a speaker, a microphone, a display, a battery, etc. The storage may be configured to store user data. The storage may be an embedded multimedia card (eMMC), a solid state drive (SSD), a universal flash storage (UFS) device, etc. The display may be implemented to display data processed by the SoC and/or to receive data through a touchscreen panel of the display.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

1. A semiconductor device comprising:
a redistribution layer comprising an insulation layer in which a first wiring pattern is formed;
a first semiconductor chip, on the redistribution layer in a first direction, connected to the first wiring pattern; and
a first capacitor disposed in the redistribution layer.

2. The semiconductor device of claim 1, wherein the first capacitor is disposed in the insulation layer such that one of a top surface and a bottom surface of the first capacitor is within the insulation layer in the first direction, and the other of the top surface and the bottom surface of the first capacitor is within the insulation layer in the first direction or coplanar with a top surface or a bottom surface of the insulation layer.

3. The semiconductor device of claim 2, wherein the top surface of the first capacitor is coplanar with the top surface of the insulation layer.

4. The semiconductor device of claim 1, wherein the first capacitor is disposed to be closer to a top surface of the redistribution layer facing the first semiconductor chip than a bottom surface of the redistribution layer facing away from the first semiconductor chip in the first direction.

5. The semiconductor device of claim 1, wherein the first capacitor is connected to the first wiring pattern which is connected to the first semiconductor chip.

6. The semiconductor device of claim 5, further comprising a second capacitor connected to a second wiring pattern formed in the redistribution layer,
wherein the second wiring pattern is electrically isolated from any wiring pattern connected to the first semiconductor chip.

7. The semiconductor device of claim 1, wherein the first capacitor is connected to the first wiring pattern,
wherein the first wiring pattern is electrically isolated from any wiring pattern connected to the first semiconductor chip.

8. The semiconductor device of claim 1, further comprising:
a second semiconductor chip, on the redistribution layer in a first direction, connected to a second wiring pattern in the redistribution layer; and
a second capacitor disposed in the redistribution layer.

9. The semiconductor device of claim 8, wherein the first capacitor and the second capacitor are connected to the first wiring pattern and the second wiring pattern, respectively, and
wherein at least one of the first wiring pattern and the second wiring pattern is connected to at least one of the first semiconductor chip and the second semiconductor chip.

10. The semiconductor device of claim 8, wherein the first capacitor and the second capacitor are disposed closer to a top surface of the redistribution layer facing the first semiconductor chip and the second semiconductor chip than an opposite outer surface of the redistribution layer facing away from the first semiconductor chip and the second semiconductor chip.

11. The semiconductor device of claim 1, further comprising a connection terminal between the redistribution layer and the first semiconductor chip,
wherein the connection terminal comprises a solder ball or a bump connecting the first wiring pattern or another wiring pattern in the redistribution layer to the first semiconductor chip.

12. An electronic device comprising:
a semiconductor chip;
an insulation layer disposed on the semiconductor chip in a first direction, and comprising a first wiring pattern therein which is connected to the semiconductor chip;
a capacitor disposed in the insulation layer.

13. The electronic device of claim 12, wherein the capacitor is disposed in the insulation layer to be closer to a top surface of the insulation layer facing the semiconductor chip than a bottom surface of the insulation layer facing away from the semiconductor chip in the first direction.

14. The electronic device of claim 12, wherein the insulation layer comprises a plurality of layers which are stacked in the first direction, and
wherein a thickness of the capacitor is smaller than a thickness of one of the plurality of layers in the first direction.

15. The electronic device of claim 12, wherein the insulation layer comprises a second wiring pattern,
wherein the capacitor is connected to the semiconductor chip though one of the first wiring pattern and the second wiring pattern.

16. The electronic device of claim 12, further comprising a connection terminal formed between the insulation layer and the semiconductor chip,
wherein the connection terminal comprises a solder ball or a bump connecting the first wiring pattern to the semiconductor chip.

17. An electronic system comprising a first semiconductor package on a substrate, the first semiconductor package comprising:
a first redistribution layer comprising a first insulation layer in which a first wiring patterns is formed;
a semiconductor chip which is provided on the first redistribution layer, and connected to the first wiring pattern; and
a first capacitor disposed in the first redistribution layer.

18. The electronic system of claim 17, wherein the first capacitor is disposed in the first insulation layer such that one of a top surface and a bottom surface of the first capacitor is within the first insulation layer in a first direction, and the other of the top surface and the bottom surface of the first capacitor is within the first at least one insulation layer in the first direction or coplanar with a top surface or a bottom surface of the first insulation layer.

19. The electronic system of claim 18, wherein the first capacitor is disposed to be closer to a top surface of the first redistribution layer facing the semiconductor chip than a bottom surface of the first redistribution layer facing away from the semiconductor chip in the first direction.

20-22. (canceled)
